(19) United States
(12) Patent Application Publication
(10) Pub. No.: US 2018/0102079 A1
(43) Pub. Date: Apr. 12, 2018

(54) THIN FILM TRANSISTOR ARRAY SUBSTRATE, MANUFACTURING METHOD THEREOF AND LIQUID CRYSTAL DISPLAY PANEL USING THE SAME

(71) Applicant: Shenzhen China Star Optoelectronics Technology Co., Ltd., Shenzhen (CN)

(72) Inventor: Liwang SONG, Shenzhen (CN)

(21) Appl. No.: 15/325,442

(22) PCT Filed: Dec. 14, 2016
(86) PCT No.: PCT/CN2016/109861

§ 371 Date: Jan. 11, 2017

(30) Foreign Application Priority Data
Oct. 12, 2016 (CN) 201610891224.5

(51) Int. Cl. G09G 3/20; G09G 3/36; G02F 1/1335; H01L 27/12

(52) U.S. Cl. CPC G09G 3/2003; G09G 3/364; G09G 3/3648; G02F 2001/136222; H01L 27/1214; G09G 2300/0804; G02F 1/133514

(57) ABSTRACT

A thin film transistor array substrate, a manufacturing method thereof and a liquid crystal display using the same are provided. The array substrate includes an array substrate base, a thin film transistor (TFT) array layer, a color filter layer, a pixel electrode passivation layer, a pixel electrode connected with the TFT array layer through a via hole, and a patterned recessed microstructure disposed on a surface of the color filter layer. Thus, the patterned recessed microstructure is formed on the surface of the color filter layer through a mask forming the via hole without increasing the manufacturing cost, so that the volatiles generated by the process of the color resist and the subsequent high temperature process of the pixel electrode passivation layer are completely released to avoid gas residues, eliminate the possibility of bubbles in products in later period, and improve the quality of the product.

### FIELD OF THE INVENTION

The disclosure relates to liquid crystal display technology, and more particularly to a thin film transistor array substrate, manufacturing of the thin film transistor array substrate and liquid crystal display using the same.

### BACKGROUND OF THE INVENTION

Liquid crystal display (LCD) is one of the most widely used panel displays. LCD panel is the core component of the liquid crystal display. COA (Color Filter on Array) technique is used to improve the aperture ratio and reduce the parasitic capacitance effect in AMLCD fabrication technology.

COA (Color Filter on Array) technology is a technology of directly disposing a color filter layer on an array substrate. The color filter layer is only provided with a black matrix (BM) and a columnar spacer (Photo Spacer, PS) layer.

The color filter layer is mainly made of an organic material. When the color filter layer is produced in the conventional technology, a gas may remain in the interior of the color filter layer. Meanwhile due to the characteristics of the organic material, under certain conditions, such as high temperature environment, the color filter layer will slowly release small molecules of carbon oxide gas, such as CO, CO₂. These small molecules will penetrate the surface of the color filter layer and the other structural layers into the liquid crystal layer, and form bubbles locally, thereby affecting the display effect and reducing the yield of the product.

At present, there is a need to design holes to make the gas in the color resist volatilized out. However, the volatilization is not sufficient and the preparation process of the holes is difficult to control, so that the quality of COA product is not stable.

### SUMMARY OF THE INVENTION

The disclosure provides a thin film transistor array substrate, manufacturing of the thin film transistor array substrate and liquid crystal display using the same for releasing the gas generated by a color resist layer, improving the quality of the product and solving the problem of forming bubbles.

In order to solve the aforementioned problem, the disclosure provides a thin film transistor array substrate, which comprises an array substrate base, a thin film transistor array layer disposed on the array substrate base, a color filter layer disposed on the thin film transistor array layer and the array substrate base, a pixel electrode passivation layer disposed on the color filter layer, a pixel electrode disposed on the pixel electrode passivation layer, and connected with the thin film transistor array layer through a via hole. Besides, a patterned recessed microstructure is disposed on a surface of the color filter layer.

Moreover, the thin film transistor array layer comprises a gate metal layer disposed on the array substrate base, a gate passivation layer disposed on the gate metal layer and the array substrate base, a channel region disposed on the gate passivation layer, a first passivation layer disposed on the channel region, a source-drain metal layer disposed on the first passivation layer, a second passivation layer disposed on the source-drain metal layer, and the color filter layer disposed on the second passivation layer.

Moreover, the color filter layer comprises a plurality of color resist units sequentially connected with each other, and each of the color resist units is provided with the patterned recessed microstructure thereon.

In addition, each of the color resist units comprises a red color resist unit, a green color resist unit and a blue color resist unit.

The disclosure further provides a liquid crystal display panel including a thin film transistor array substrate and a color film substrate. The thin film transistor array substrate adapts the thin film transistor array substrate described above. The color film substrate comprises a color film substrate base, a black matrix disposed on the color film substrate base and a columnar spacer disposed on the black matrix.

The disclosure further provides a method for manufacturing a thin film transistor array substrate comprising the steps of:
providing an array substrate base;
disposing a thin film transistor array layer on the array substrate base;
disposing a color filter layer on the thin film transistor array layer and the array substrate base;
forming a via hole penetrating the color filter layer and exposing a drain of the thin film transistor array layer, and forming a patterned recessed microstructure on a surface of the color filter layer through a mask by which the via hole is formed;
disposing a pixel electrode passivation layer on the color filter layer; and
disposing a pixel electrode disposed on the pixel electrode passivation layer, wherein a pattern of the pixel electrode is the same as a pattern of the recessed microstructure in the corresponding position of the recessed microstructure.

In addition, the step of disposing a thin film transistor array layer on the array substrate base further comprises the steps:
forming a gate metal layer on the array substrate base;
disposing a gate passivation layer on the gate metal layer and the array substrate base;
forming a channel region on the gate passivation layer;
disposing a first passivation layer on the channel region;
disposing a source-drain metal layer on the first passivation layer;
disposing a second passivation layer on the source-drain metal layer;
disposing the color filter layer on the second passivation layer.

In addition, the color filter layer comprises a plurality of color resist units sequentially connected with each other, and each of the color resist units is provided with the patterned recessed microstructure thereon.

In addition, the color filter layer is dry-etched to form the via hole and the recessed microstructure.

In addition, a transparent electrode layer is formed on the pixel electrode passivation layer and on a surface of the recessed microstructure, the transparent electrode layer is wet-etched to form the pixel electrode.

The disclosure has the advantages of forming the patterned recessed microstructure on the surface of the color filter layer through a mask by which the via hole is formed without increasing the manufacturing cost, so that the volatiles generated by the process of manufacturing the color resist and the subsequent high temperature process of manufacturing the pixel electrode passivation layer are completely released to avoid gas residues, eliminate the possibility of bubbles in products in later period, and improve the quality of the product.

### DESCRIPTION OF THE DRAWINGS

FIG. 1 is a structural schematic view of a thin film transistor array substrate of the disclosure.

FIG. 2 is a sectional view of line A-A in FIG. 1.

FIG. 3 is a procedure schematic view of a method for manufacturing a thin film transistor array substrate of the disclosure.

FIGS. 4A-4F are flow charts of a process of the method for manufacturing a thin film transistor array substrate of the disclosure.

### DETAILED DESCRIPTION OF THE PREFERRED EMBODIMENTS

In order to more clearly describe the thin film transistor array substrate, manufacturing of the thin film transistor array substrate and liquid crystal display using the same of the disclosure, the following description is used to make a simple introduction of the drawings used in the following embodiments.

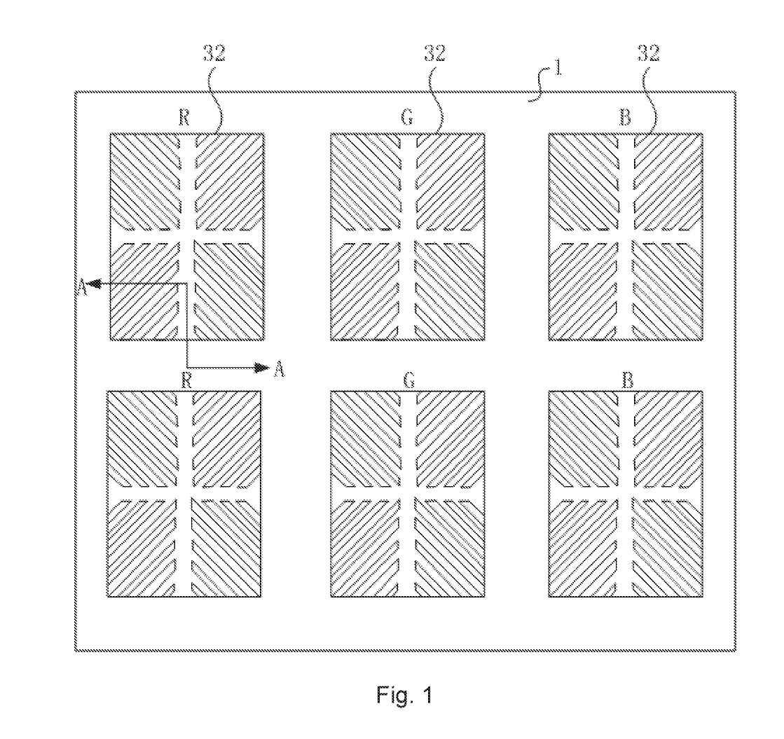

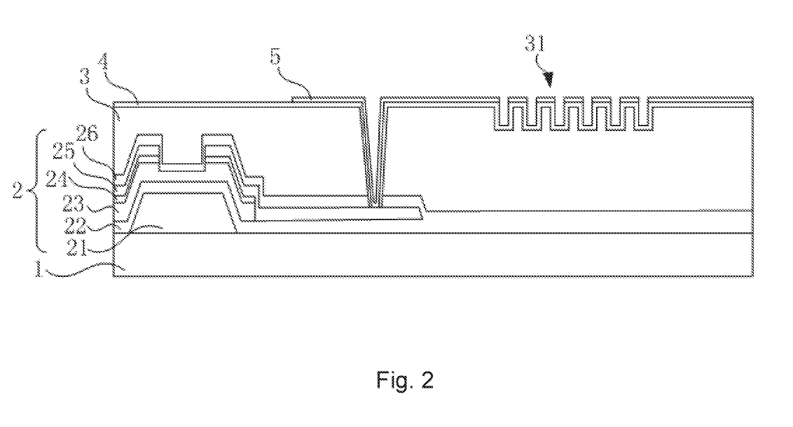

Refer to FIG. 1 and FIG. 2, the disclosure provides a thin film transistor array substrate, which comprises an array substrate base 1, a thin film transistor array layer 2 disposed on the array substrate base 1, a color filter layer 3 disposed on the thin film transistor array layer 2 and the array substrate base 1, a pixel electrode passivation layer 4 disposed on the color filter layer 3, and a pixel electrode 5 disposed on the pixel electrode passivation layer 4. In addition, the array substrate base 1 is preferably a glass substrate.

The thin film transistor array layer 2 comprises a gate metal layer 21 disposed on the array substrate base 1, a gate passivation layer 22 disposed on the gate metal layer 21 and the array substrate base 1, a channel region 23 disposed on the gate passivation layer 22, a first passivation layer 24 disposed on the channel region 23, a source-drain metal layer 25 disposed on the first passivation layer 24, a second passivation layer 26 disposed on the source-drain metal layer 25. The color filter layer 3 is disposed on the second passivation layer 26.

A patterned recessed microstructure 31 is disposed on a surface of the color filter layer 3. The gas generated by the process of manufacturing the color resist and the subsequent high temperature process of manufacturing the pixel electrode passivation layer can be released through the recessed microstructure 31, thereby avoiding the formation of bubbles and affecting the quality of the product.

Refer to FIG. 1, the color filter layer 3 comprises a plurality of color resist units 32 sequentially connected with each other. The color resist unit 32 comprises a red color resist unit R, a green color resist unit G and a blue color resist unit B. The red color resist unit R, the green color resist unit G and the blue color resist unit B are alternately arranged to form the color filter layer 3. Furthermore, the color resist unit 32 further comprises a white color resist unit (not shown). Each of the color resist units 32 is provided with the patterned recessed microstructure 31 thereon. In the specific embodiment, after the pixel electrode passivation layer 4 is covered by the color resist unit 32, the pixel electrode passivation layer 4 is patterned to form a patterned pixel electrode 5 as shown in FIG. 1 in a subsequent process.

In another embodiment of the disclosure, an inner surface of the recessed microstructure 31 is also covered by the pixel electrode passivation layer 4. The pixel electrode 5 is deposited on the surface of the pixel electrode passivation layer 4. The inner surface of the recessed microstructure 31 is not deposited by the pixel electrode, so that a pattern of the pixel electrode 5 is the same as a pattern of the recessed microstructure 31 in the corresponding position of the recessed microstructure 31. Thus, the patterned pixel electrode 5 is formed, so that a process of forming the patterned pixel electrode 5 through patterning the pixel electrode passivation layer 4 in the conventional technology is omitted for saving cost and shortening the process time.

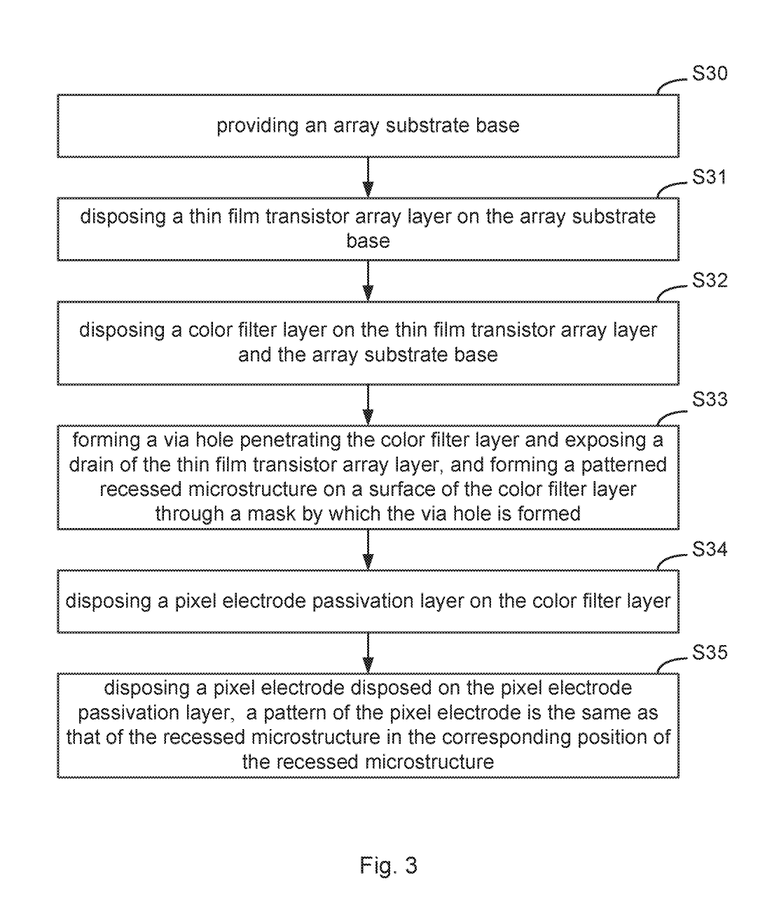

Refer to FIG. 3, the disclosure further provides a method for manufacturing a thin film transistor array substrate comprising the steps of:

step S30: providing an array substrate base;

step S31: disposing a thin film transistor array layer on the array substrate base;

step S32: disposing a color filter layer on the thin film transistor array layer and the array substrate base;

step S33: forming a via hole penetrating the color filter layer and exposing a drain of the thin film transistor array layer, and forming a patterned recessed microstructure on a surface of the color filter layer through a mask by which the via hole is formed;

step S34: disposing a pixel electrode passivation layer on the color filter layer;

step S35: disposing a pixel electrode on the pixel electrode passivation layer. In addition, a pattern of the pixel electrode is the same as a pattern of the recessed microstructure in the corresponding position of the recessed microstructure.

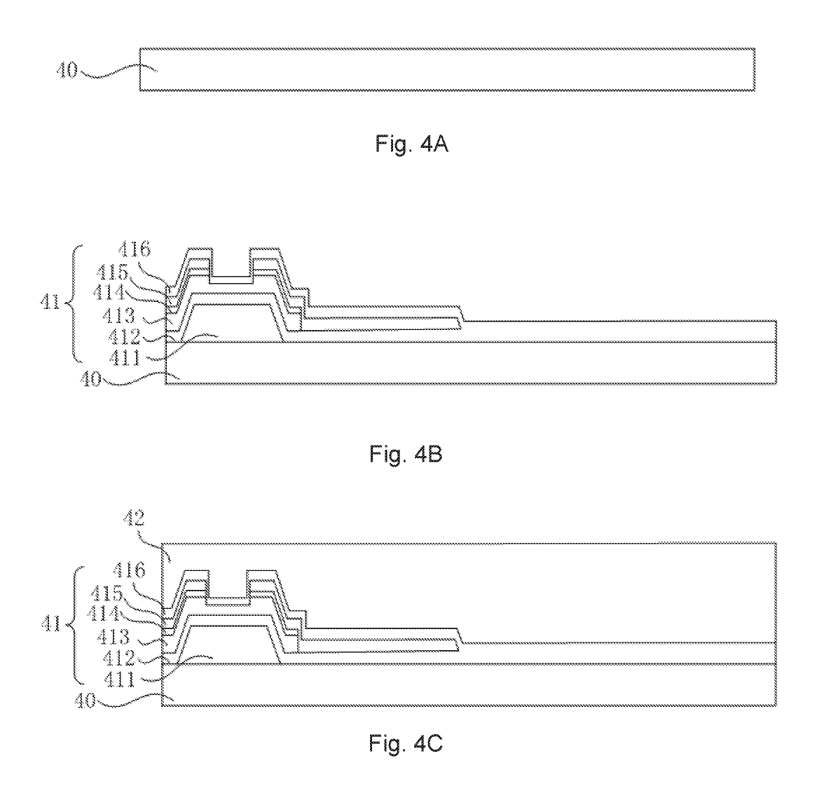

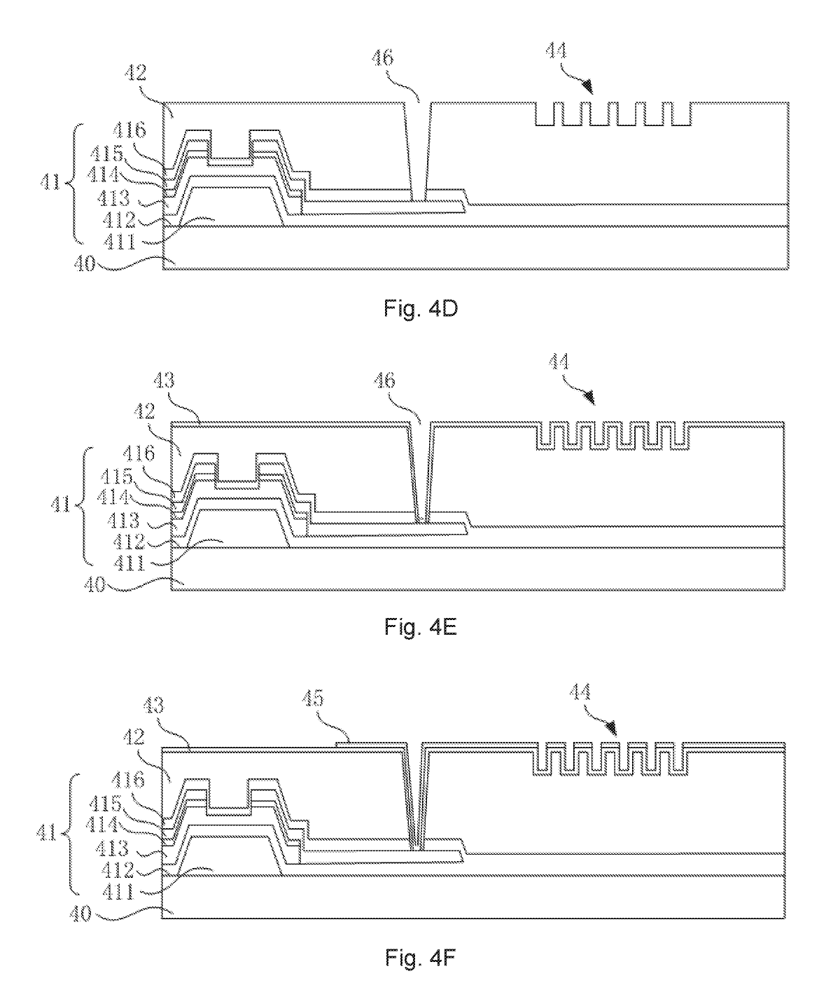

Refer to FIGS. 4A-4F, which are flow charts of a process of the method for manufacturing a thin film transistor array substrate of the disclosure.

Refer to FIG. 4A and the step S30, an array substrate base 40 is provided, the array substrate base 40 is preferably a glass substrate.

Refer to FIG. 4B and the step S31, a thin film transistor array layer 41 is disposed on the array substrate base 40.

The step of manufacturing the thin film transistor array layer 41 further comprises the following steps:

(1) forming a gate metal layer 411 on the array substrate base 41;

(2) disposing a gate passivation layer 412 on the gate metal layer 411 and the array substrate base 40;

(3) forming a channel region 413 on the gate passivation layer 412;

(4) disposing a first passivation layer 414 on the channel region 413;

(5) disposing a source-drain metal layer 415 on the first passivation layer 414;

(6) disposing a second passivation layer 416 on the source-drain metal layer 415.

The method of manufacturing the thin film transistor array layer 41 can be obtained from the conventional technology by a person skilled in the art, and will not be described in detail herein.

Refer to FIG. 4C and the step S32, a color filter layer 42 is disposed on the thin film transistor array layer 41 and the array substrate base 40. In addition, the color filter layer 42 is formed on the second passivation layer 416, and the color filter layer 42 may be formed by a coating method. The color filter layer 42 includes a plurality of color resist units sequentially connected with each other. The color resist unit 42 comprises a red color resist unit, a green color resist unit and a blue color resist unit, and the red hue unit, the green hue unit, and the red color resist unit, the green color resist unit and the blue color resist unit are alternately arranged to form the color filter layer 42.

Refer to FIG. 4D and the step S33, a via hole 46 penetrating the color filter layer 42 and exposing a drain of the thin film transistor array layer is formed, and a patterned recessed microstructure 44 is formed on a surface of the color filter layer 42 through a mask by which the via hole 46 is formed. One having ordinary skill in the art can obtain the process for forming the via hole 46 from the conventional technology. Take the disclosure for example, the process comprises: forming a mask on the color filter layer 42; patterning the mask; exposing a position of the via hole and exposing a position of the recessed microstructure 44; performing dry etching for forming the via hole 46 and the patterned recessed microstructure 44.

In the disclosure, in forming the via hole 46, the mask forming the via hole 46 also acts as a mask for forming the patterned recessed microstructures 44 to form the patterned recessed microstructures 44 without additional processing and without increasing the manufacturing costs. The gas generated in the process of manufacturing the color filter layer 42 and the subsequent high temperature process of manufacturing a pixel electrode passivation layer 43 can be released through the recessed microstructure 44 4, thereby avoiding the formation of bubbles and affecting the quality of the product.

Refer to FIG. 4E and the step S34, a pixel electrode passivation layer 43 is formed on the color filter layer 42.

Refer to FIG. 4F and the step S35, a pixel electrode 45 is disposed on the pixel electrode passivation layer 43. Firstly, a transparent electrode layer is formed on the pixel electrode passivation layer 43, the transparent electrode layer is wet-etched to form the pixel electrode. In this embodiment, in a corresponding position of the patterned recessed microstructure 44, the pixel electrodes may be patterned on the basis of the patterned recessed microstructure 44. The pixel electrodes 45 is directly deposited to form the same pattern, so that the step of forming the pixel electrode 45 by patterning the pixel electrode passivation layer 43 in the prior art can be omitted. In another embodiment of the disclosure, the pixel electrode passivation layer 43 may be patterned after the pixel electrode passivation layer 43 is formed on the color filter layer 42. Thus, in the subsequent process of depositing the pixel electrode 45, a patterned pixel electrode 45 is formed.

The disclosure further provides a liquid crystal display panel (not shown), which is a COA liquid crystal display panel, that is, a color filter layer and a TFT array are disposed on the same side. The basic structure of the liquid crystal display panel of the disclosure is the same as that of a conventional COA liquid crystal display panel. The liquid crystal display panel includes a thin film transistor array substrate and a color film substrate. The thin film transistor array substrate is the same as the above-mentioned thin film transistor array substrate. The color film substrate comprises a color film substrate base, a black matrix disposed on the color film substrate base and a columnar spacer disposed on the black matrix. The improvement of the liquid crystal display panel of the disclosure resides in the thin film transistor array substrate.

The disclosure has been described with preferred embodiments thereof, and it is understood that many changes and modifications to the described embodiment can be carried out without departing from the scope and the spirit of the invention that is intended to be limited only by the appended claims.

What is claimed is:

1. A thin film transistor array substrate, comprising:
an array substrate base;
a thin film transistor array layer disposed on the array substrate base;
a color filter layer disposed on the thin film transistor array layer and the array substrate base;
a pixel electrode passivation layer disposed on the color filter layer; and
a pixel electrode disposed on the pixel electrode passivation layer, and connected with the thin film transistor array layer through a via hole;
wherein a patterned recessed microstructure is disposed on a surface of the color filter layer;
wherein the thin film transistor array layer includes: a gate metal layer disposed on the array substrate base, a gate passivation layer disposed on the gate metal layer and the array substrate base, a channel region disposed on the gate passivation layer, a first passivation layer disposed on the channel region, a source-drain metal layer disposed on the first passivation layer, and a second passivation layer disposed on the source-drain metal layer; and
wherein the color filter layer is disposed on the second passivation layer, and includes a plurality of color resist units sequentially connected with each other, each of the color resist units is provided with the patterned recessed microstructure thereon; and each of the color resist units comprises a red color resist unit, a green color resist unit and a blue color resist unit.

2. A thin film transistor array substrate, comprising:
an array substrate base;
a thin film transistor array layer disposed on the array substrate base;
a color filter layer disposed on the thin film transistor array layer and the array substrate base;
a pixel electrode passivation layer disposed on the color filter layer; and
a pixel electrode disposed on the pixel electrode passivation layer, and connected with the thin film transistor array layer through a via hole;
wherein a patterned recessed microstructure is disposed on a surface of the color filter layer.

3. The thin film transistor array substrate according to claim 2, wherein the thin film transistor array layer comprises a gate metal layer disposed on the array substrate base, a gate passivation layer disposed on the gate metal layer and the array substrate base, a channel region disposed on the gate passivation layer, a first passivation layer disposed on the channel region, a source-drain metal layer disposed on the first passivation layer, and a second passivation layer disposed on the source-drain metal layer, wherein the color filter layer is disposed on the second passivation layer.

4. The thin film transistor array substrate according to claim 2, wherein the color filter layer comprises a plurality of color resist units sequentially connected with each other, and each of the color resist units is provided with the patterned recessed microstructure thereon.

5. The thin film transistor array substrate according to claim 4, wherein each of the color resist units comprises a red color resist unit, a green color resist unit and a blue color resist unit.

6. A liquid crystal display panel, comprising a thin film transistor array substrate according to claim 2 and a color film substrate, wherein the color film substrate comprises a color film substrate base, a black matrix disposed on the color film substrate base, and a columnar spacer disposed on the black matrix.

7. A method for manufacturing a thin film transistor array substrate, comprising steps of:
providing an array substrate base;
disposing a thin film transistor array layer on the array substrate base;
disposing a color filter layer on the thin film transistor array layer and the array substrate base;
forming a via hole penetrating the color filter layer and exposing a drain of the thin film transistor array layer, and forming a patterned recessed microstructure on a surface of the color filter layer through a mask by which the via hole is formed;
disposing a pixel electrode passivation layer on the color filter layer; and
disposing a pixel electrode disposed on the pixel electrode passivation layer, wherein a pattern of the pixel electrode is the same as that of the recessed microstructure in the corresponding position of the recessed microstructure.

8. The method for manufacturing a thin film transistor array substrate according to claim 7, wherein the step of disposing a thin film transistor array layer on the array substrate base further comprises steps of:
forming a gate metal layer on the array substrate base;
disposing a gate passivation layer on the gate metal layer and the array substrate base;
forming a channel region on the gate passivation layer;
disposing a first passivation layer on the channel region;
disposing a source-drain metal layer on the first passivation layer; and
disposing a second passivation layer on the source-drain metal layer, wherein the color filter layer is disposed on the second passivation layer.

9. The method for manufacturing a thin film transistor array substrate according to claim 7, wherein the color filter layer comprises a plurality of color resist units sequentially connected with each other, and each of the color resist units is provided with the patterned recessed microstructure thereon.

10. The method for manufacturing a thin film transistor array substrate according to claim 7, wherein the color filter layer is dry-etched to form the via hole and the recessed microstructure.

11. The method for manufacturing a thin film transistor array substrate according to claim 7, wherein a transparent electrode layer is formed on the pixel electrode passivation layer and on a surface of the recessed microstructure, the transparent electrode layer is wet-etched to form the pixel electrode.
